(19) United States
(12) Patent Application Publication
(10) Pub. No.: US 2026/0068444 A1
(43) Pub. Date: Mar. 5, 2026

(54) DISPLAY PANEL AND DISPLAY DEVICE

(71) Applicant: Hefei Visionox Technology Co., Ltd., Hefei (CN)

(72) Inventor: Zhiwei ZHOU, Hefei (CN)

(73) Assignee: Hefei Visionox Technology Co., Ltd., Hefei (CN)

(21) Appl. No.: 19/305,690

(22) Filed: Aug. 20, 2025

(30) Foreign Application Priority Data
Aug. 28, 2024 (CN) 202411200614.4

(51) Int. Cl. H10K 59/123; H10K 59/122; H10K 59/124; H10K 59/80

(52) U.S. Cl. CPC H10K 59/123; H10K 59/122; H10K 59/124; H10K 59/8731

(57) ABSTRACT

The present application provides a display panel and a display device. The display panel has a first area and a second area located on at least one side of the first area. The display panel includes a substrate, a first conductor layer, a pixel definition layer, and a first protective layer. The first conductor layer is arranged on a side of the substrate, and the first conductor layer includes a mark portion located within the second area. The pixel definition layer is arranged on a side of the first conductor layer facing away from the substrate. The first protective layer is arranged between the pixel definition layer and the first conductor layer, and an orthographic projection of the mark portion on the substrate is located within orthographic projections of the first protective layer and the pixel definition layer on the substrate.

### CROSS-REFERENCE TO RELATED APPLICATIONS

The present application claims priority to the Chinese Patent Application No. 202411200614.4, filed on Aug. 28, 2024, and the entire contents of the aforementioned application are hereby incorporated by reference in its entirety.

### FIELD

The present application relates to the field of display equipment, and particularly to a display panel and a display device.

### BACKGROUND

Flat display panels such as organic light emitting diode (OLED) display panels and display panels using light emitting diode (LED) devices have been widely applied to various consumer electronic products such as mobile phones, televisions, personal digital assistants, digital cameras, notebook computers and desktop computers and predominate in display devices thanks to their advantages such as high image quality, energy efficiency, slim design and a wide range of applications.

### SUMMARY

Embodiments of the present application provide a display panel and a display device, which can improve the reliability of the display panel.

The embodiments of the present application provide a display panel. The display panel has a first area and a second area located on at least one side of the first area. The display panel includes a substrate, a first conductor layer, a pixel definition layer, and a first protective layer. The first conductor layer is arranged on a side of the substrate, and the first conductor layer includes a mark portion located within the second area. The pixel definition layer is arranged on a side of the first conductor layer facing away from the substrate. The first protective layer is arranged between the pixel definition layer and the first conductor layer, and an orthographic projection of the mark portion on the substrate is located within orthographic projections of the first protective layer and the pixel definition layer on the substrate.

The embodiments of the present application provide a display device. The display device includes a display panel in the proceeding implementation.

The embodiments of the present application provide a display panel and a display device, in which the mark portion can be covered and shielded by the pixel definition layer and the first protective layer, and during subsequent etching processes, the mark portion can be dually protected by means of two film layers, i.e., the pixel definition layer and the first protective layer, to reduce the risk of the mark portion being damaged by etching, and thus improve the positioning precision corresponding to subsequent manufacturing processes and improve the reliability of the display panel.

### BRIEF DESCRIPTION OF THE DRAWINGS

FIG. 1 is a schematic structural diagram of a display panel in the related art;

FIG. 2 is a schematic diagram of a cross-sectional structure at a first area of a display panel according to an embodiment of the present application;

FIG. 3 is a schematic diagram of a cross-sectional structure at a second area of a display panel according to an embodiment of the present application;

FIG. 4 is a schematic diagram of a cross-sectional structure at a second area of another display panel according to an embodiment of the present application;

FIG. 5 is a schematic diagram of a cross-sectional structure at a first area of still another display panel according to an embodiment of the present application;

FIG. 6 is a schematic diagram of a cross-sectional structure at a first area of yet another display panel according to an embodiment of the present application;

FIG. 7 is a schematic diagram of a cross-sectional structure at a first area of still yet another display panel according to an embodiment of the present application;

FIG. 8 is a schematic diagram of a cross-sectional structure at a second area of a further display panel according to an embodiment of the present application;

FIG. 9 is a schematic diagram of a cross-sectional structure at a first area of a still further display panel according to an embodiment of the present application;

FIG. 10 is a schematic diagram of an enlarged structure at an area Q in FIG. 2;

FIG. 11 is a schematic diagram of a cross-sectional structure at a second area of a yet further display panel according to an embodiment of the present application; and

FIG. 12 is a schematic structural diagram of a display device according to an embodiment of the present application.

### LIST OF REFERENCE SIGNS

10. Substrate;
20. First conductor layer; 21. Mark portion; 22. First conductor portion;
30. Pixel definition layer; 31. Pixel opening; 32. Third sub-portion; 33. Fourth sub-portion; 34. Sixth sub-portion;
40. First protective layer; 41. First sub-portion; 42. Second sub-portion; 43. Fifth sub-portion; 44. First opening;
50. First electrode layer; 51. First electrode; 52. Second conductor portion;
60. Isolation structure; 61. Isolation opening; 62. First isolation portion; 63. Second isolation portion; 64. Third isolation portion;
71. First encapsulation layer; 711. Encapsulation portion; 72. Second encapsulation layer;
73. Third encapsulation layer;
80. Planarization layer; 81. First flat portion; 82. Second flat portion;
M1. First surface; M2. Second surface; M3. Third surface; M4. Fourth surface;
P. Light-emitting structure; J. Second electrode;
A1. First area; A2. Second area.

### DETAILED DESCRIPTION OF THE EMBODIMENTS

In a display panel, an alignment mark is typically provided in the display panel and can be used to identify equipment, facilitating positioning and improving the manufacturing efficiency and preparation precision of the display panel. The alignment mark is generally made of a conductor material, and after the alignment mark is formed, there are typically multiple etching processes, and these etching processes may easily cause damage to the alignment mark by etching, affecting the identification and positioning of the alignment mark in subsequent manufacturing processes.

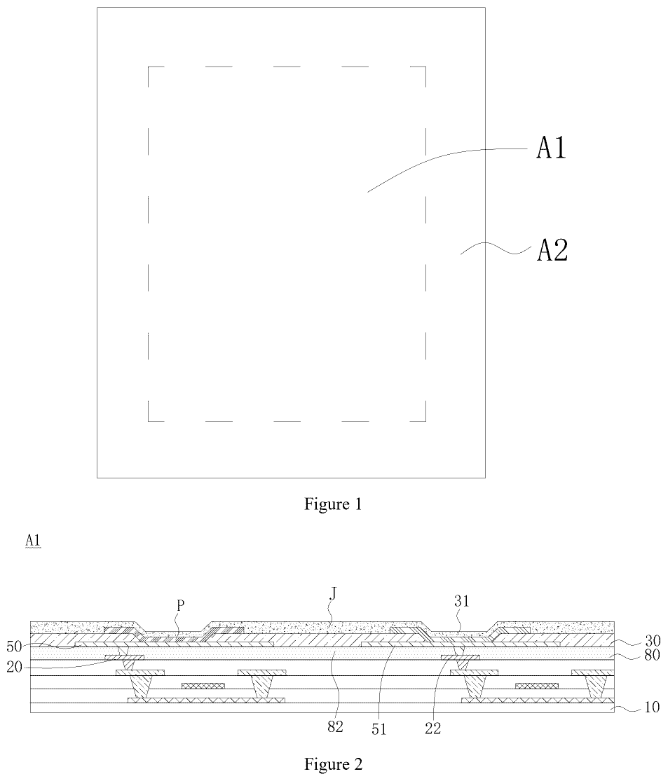

In view of the above problems, in some embodiments, referring to FIGS. 1 to 3, embodiments of the present application provide a display panel. The display panel has a first area A1 and a second area A2 located on at least one side of the first area A1. The display panel includes a substrate 10, a first conductor layer 20, a pixel definition layer 30, and a first protective layer 40. The first conductor layer 20 is arranged on a side of the substrate 10, and the first conductor layer 20 includes a mark portion 21 located within the second area A2. The pixel definition layer 30 is arranged on a side of the first conductor layer 20 facing away from the substrate 10. The first protective layer 40 is arranged between the pixel definition layer 30 and the first conductor layer 20, and an orthographic projection of the mark portion 21 on the substrate 10 is located within orthographic projections of the first protective layer 40 and the pixel definition layer 30 on the substrate 10.

The display panel has at least the first area A1 and the second area A2 located on a peripheral side of the first area A1. The first area A1 is an area in the display panel that is used to realize a display function, and the second area A2 is an area in the display panel that does not realize the display function. The size, shape, etc., of the first area A1 and the second area A2 are not limited in the embodiments of the present application. In one embodiment, the second area A2 is arranged around the peripheral side of the first area A1. Further, in one embodiment, the shape of the first area A1 is adapted to the shape of the second area A2. For example, the first area A1 is of a square structure, and the second area A2 is of a square ring structure.

The substrate 10 mainly functions as a support and carrier, and the other film layers are sequentially stacked on the substrate 10. The “stacked” mentioned here means that the other film layers are arranged sequentially in a thickness direction of the substrate 10, where thickness directions of the other film layers on the substrate 10 are generally consistent with the thickness direction of the substrate 10 itself. Therefore, for ease of illustration, the thickness direction of the substrate 10 or the thickness directions of the other film layers mentioned later in the embodiments of the present application are all indicated by the same direction.

The first conductor layer 20 is a film layer arranged on a side of the substrate 10 and including a conductor material, the first conductor layer 20 includes the mark portion 21 located within the second area A2, and the mark portion 21 is a conductor structure for implementing a positioning function. The mark portion 21 may have various structural forms, which are not limited in the embodiments of the present application. For example, the orthographic projection of the mark portion 21 on the substrate 10 may be cross-shaped, L-shaped, etc.

It should be noted that the first conductor layer 20 may include only the mark portion 21, that is, the first conductor layer 20 is completely located within the second area A2 and outside the first area A1. In one embodiment, in addition to the mark portion 21 located within the second area A2, the first conductor layer 20 may further include other conductor structures located within the first area A1. A specific layout of the conductor structures in the first conductor layer 20 is not limited in the embodiments of the present application.

Further, a specific position of the first conductor layer 20 in the thickness direction is also not limited in the embodiments of the present application. In one embodiment, the first conductor layer 20 may be an anode layer, that is, an anode structure may be provided in the first conductor layer 20. In one embodiment, the first conductor layer 20 may also be another conductor layer located on a side of the anode layer facing the substrate 10.

The pixel definition layer 30 is arranged on the side of the first conductor layer 20 facing away from the substrate 10, and the first protective layer 40 is arranged between the pixel definition layer 30 and the first conductor layer 20, that is, the first protective layer 40 and the pixel definition layer 30 are both film layer structures formed after the first conductor layer 20. On this basis, the orthographic projections of the first protective layer 40 and the pixel definition layer 30 on the substrate 10 both overlap with the orthographic projection of the mark portion 21 on the substrate 10, that is, the first protective layer 40 and the pixel definition layer 30 may both cover the mark portion 21 to protect the mark portion 21. The first protective layer 40 and the mark portion 21 may be arranged in direct contact with each other, or other film layers may be provided between the first protective layer 40 and the mark portion 21, which is not limited in the embodiments of the present application.

In the related art, an alignment mark is generally covered and shielded by only the pixel definition layer 30 above the alignment mark, the etching damage to the alignment mark caused by the etching processes cannot be avoided by relying on only the pixel definition layer 30, which may easily affect the positioning precision in subsequent manufacturing processes.

However, in the embodiments of the present application, the mark portion 21 can be covered and shielded by the pixel definition layer 30 and the first protective layer 40, and during subsequent etching processes, the mark portion 21 can be dually protected by means of two film layers, i.e., the pixel definition layer 30 and the first protective layer 40, to reduce the risk of the mark portion 21 being damaged by etching, and thus improve the positioning precision corresponding to subsequent manufacturing processes and improve the reliability of the display panel.

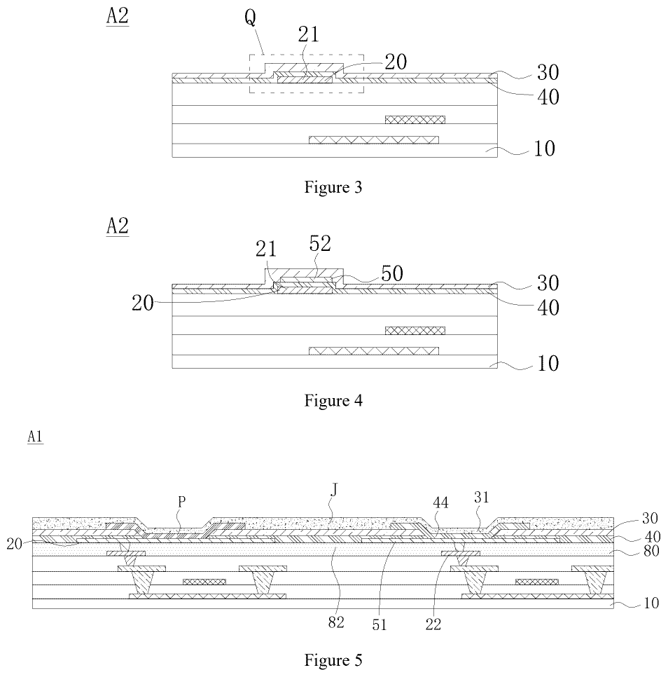

In some embodiments, as shown in FIGS. 2 and 3, the display panel further includes a first electrode layer 50 arranged between the pixel definition layer 30 and the first conductor layer 20. The first electrode layer 50 includes first electrodes 51 located within the first area A1, the pixel definition layer 30 encloses pixel openings 31, and the first electrodes 51 are exposed to the pixel opening 31.

The first electrode layer 50 is arranged between the first conductor layer 20 and the pixel definition layer 30, that is, the first electrode layer 50 is formed after the first conductor layer 20 and before the pixel definition layer 30. The first electrode layer 50 includes spaced-apart first electrodes 51, and the first electrodes 51 serve as anodes for drivingly controlling whether the display panel emits light. As an example, the display panel further includes a light-emitting functional layer located on a side of the first electrode layer 50 facing away from the substrate 10, and a second electrode layer located on a side of the light-emitting functional layer facing away from the substrate 10. The light-emitting functional layer includes light-emitting structures P arranged corresponding to first electrodes 51 and located within the pixel openings 31. The second electrode layer includes second electrodes J, the second electrodes J serve as cathodes, and the first electrodes 51 and the second electrodes J jointly drivingly control whether the light-emitting structures P emit light.

It should be noted that the first electrode layer 50 may be arranged only within the first area A1 and not within the second area A2, that is, the first electrode layer 50 may include only the first electrodes 51. In one embodiment, the first electrode layer 50 may be partially located within the first area A1 and partially located within the second area A2, that is, in addition to the first electrodes 51, the first electrode layer 50 further includes other structures located within the second area A2, which is not limited in the embodiments of the present application.

In the embodiments of the present application, the first conductor layer 20 is another film layer on a side of the first electrode layer 50 facing the substrate 10. On this basis, an insulating layer located between the first conductor layer 20 and the first electrode layer 50 may also be configured to cover the mark portion 21. In this way, a protection effect on the mark portion 21 can further be improved, the risk of the mark portion 21 being damaged by etching can be reduced, and the reliability of the display panel can be improved. The first protective layer 40 may be the insulating layer located between the first conductor layer 20 and the first electrode layer 50, or the first protective layer 40 may also be another film layer other than the insulating layer, which is not limited in the embodiments of the present application.

In some embodiments, as shown in FIG. 2, the first conductor layer 20 includes first conductor portions 22 located within the first area A1. An orthographic projection of a first conductor portion 22 on the substrate 10 is located within an orthographic projection of a first electrode 51 on the substrate 10.

In addition to the mark portion 21 located within the second area A2, the first conductor layer 20 further includes the first conductor portions 22 located within the first area A1, and the first conductor portion 22 is a conductor structure which can be used to transmit a specific signal to meet the display function. The orthographic projection of the first conductor portion 22 on the substrate 10 overlaps with the orthographic projection of the first electrode 51 on the substrate 10. The first conductor portion 22 may be electrically connected to the first electrode 51, or the first conductor portion 22 may be insulated from the first electrode 51. In one embodiment, the first conductor portion 22 is electrically connected to the first electrode 51.

In some embodiments, referring to FIGS. 2 and 4, the first electrode layer 50 further includes a second conductor portion 52 located within the second area A2. An orthographic projection of the second conductor portion 52 on the substrate 10 is located within the orthographic projection of the mark portion 21 on the substrate 10.

In addition to the first electrodes 51 located within the first area A1 for controlling whether the light-emitting structures P emit light, the first electrode layer 50 further includes a second conductor portion 52 located within the second area A2. The first electrodes 51 and the second conductor portion 52 may include the same material and be formed together in the same working procedure. The first electrode 51 and the second conductor portion 52 may be electrically connected, or the first electrode 51 and the second conductor portion 52 may be insulated from each other, which is not limited in the embodiments of the present application.

On this basis, in the embodiments of the present application, the orthographic projection of the second conductor portion 52 on the substrate 10 is also configured to be located within the orthographic projection of the mark portion 21 on the substrate 10, and the second conductor portion 52 covers and protects at least part of a structure of the mark portion 21, to further reduce adverse effects of the etching processes during manufacturing on the mark portion 21 by means of the second conductor portion 52, improve the positioning precision corresponding to subsequent manufacturing processes and improve the reliability of the display panel.

It should be noted that the mark portion 21 typically achieves the positioning function in two ways. One way is by leveraging optical principles, where optical equipment identifies the mark portion, and the positioning and identification of the mark portion 21 are realized by means of the reflection of light by the mark portion 21, etc. The other way is by leveraging the principle of step difference identification. Specifically, since the mark portion 21 itself has a certain thickness, during identification of the mark portion 21, the position where the mark portion 21 is located often protrudes relative to the surrounding positions. On this basis, the positioning and identification of the mark portion 21 can be realized by means of the step difference between this protrusion and the surrounding positions.

In view of this, in the embodiments of the present application, since the second conductor portion 52 is arranged to cover and shield the mark portion 21, the mark portion 21 cannot be identified by means of optical principles. On this basis, the positioning and identification of the mark portion 21 can be realized by means of the principle of step difference identification. Alternatively, in some optional embodiments, the second conductor portion 52 may also serve as an alignment mark, and the second conductor portion 52 can be identified by means of optical principles, and the position of the mark portion 21 can be determined by means of the second conductor portion 52. Alternatively, in some optional embodiments, the orthographic projection of the mark portion on the substrate 10 may also be located outside the orthographic projection of the second conductor portion 52 on the substrate 10, and a partial structure of the mark portion exposed relative to the second conductor portion 52 may also be identified by means of optical principles, which is not limited in the embodiments of the present application.

In some embodiments, the first electrode 51 is insulated from the second conductor portion 52.

In the embodiments of the present application, the first electrode 51 and the second conductor portion 52 are insulated from each other, that is, there is no need to achieve electrical connection between them by means of direct connection or by means of other conductor structures. On this basis, the position layout of the second conductor portion 52 in the second area A2 may not be affected by the first electrode 51, and the second conductor portion 52 can be arranged to better cover the mark portion 21, thereby improving the protection effect thereof on the mark portion 21 and providing better practicability.

In some embodiments, the second conductor portion 52 is located between the first protective layer 40 and the pixel definition layer 30.

In the embodiments of the present application, the second conductor portion 52 is sandwiched between the first protective layer 40 and the pixel definition layer 30, that is, a side of the second conductor portion 52 facing away from the substrate 10 can be protected by the pixel definition layer 30 to reduce the adverse effects of the etching processes on the second conductor portion 52, and when the second conductor portion 52 is used to transmit a specific signal, the transmission reliability of the specific signal can be improved. Further, this design also enables the mark portion 21 to be covered and protected by a three-layer structure of the first protective layer 40, the second conductor portion 52 and the pixel definition layer 30, thereby enhancing the protection effect on the mark portion 21 and improving the positioning precision corresponding to subsequent manufacturing processes.

In some embodiments, the first conductor layer 20 includes first electrodes 51 located within the first area A1, the pixel definition layer 30 encloses pixel openings 31, and the first electrodes 51 are exposed to the pixel openings 31.

The first conductor layer 20 includes the first electrodes 51, that is, the first conductor layer 20 is a film layer where anodes are located. The first conductor layer 20 includes both the first electrodes 51 located within the first area A1 and the mark portion 21 located within the second area A2, and the first electrodes 51 and the mark portion 21 may include the same material and be formed together in the same working procedure. The pixel definition layer 30 is formed with pixel openings 31 within the first area A1, the pixel openings 31 are arranged corresponding to the first electrodes 51, and the first electrodes 51 are at least partially exposed to the pixel openings 31.

In the related art, when the alignment mark is arranged in the anode layer, the alignment mark can often be covered and protected by only the pixel definition layer 30, which may easily cause the problem of the alignment mark being damaged by etching. However, in the embodiments of the present application, the first protective layer 40 is additionally added in the display panel, the first protective layer 40 is located between the first conductor layer 20 and the pixel definition layer 30, and both the first protective layer 40 and the pixel definition layer 30 can cover and protect the mark portion 21, thereby achieving a dual protection effect on the mark portion 21, reducing the risk of the mark portion 21 being damaged by etching, improving the alignment precision in subsequent manufacturing processes, and improving the reliability of the display panel.

It should be noted that there may be various relationships between the mark portion 21 and the first electrode 51. For example, the mark portion 21 may be electrically connected to the first electrode 51, or the mark portion 21 may be insulated from the first electrode 51. In one embodiment, the mark portion 21 is insulated from the first electrode 51, that is, there is no need to achieve electrical connection between them by means of direct connection or by means of other conductor structures. On this basis, the position layout of the mark portion 21 in the second area A2 may not be affected by the first electrode 51, providing better flexibility.

Moreover, the positional relationship between the first protective layer 40 and the first electrode 51 is also not limited in the embodiments of the present application. In one embodiment, the first electrodes 51 are arranged in close contact with the pixel definition layer 30, the mark portion 21 is arranged at a distance from the pixel definition layer 30, that is, the first electrodes 51 are not separated from the pixel definition layer 30 by the first protective layer 40, and the orthographic projection of the first electrode 51 on the substrate 10 is located outside the orthographic projection of the first protective layer 40 on the substrate 10. However, the mark portion 21 is separated from the pixel definition layer 30 by the first protective layer 40, and the mark portion 21 is dually protected by means of the first protective layer 40 and the pixel definition layer 30. Further, in one embodiment, the first protective layer 40 may be completely located within the second area A2 and outside the first area A1.

Alternatively, in other embodiments, referring to FIG. 5, the first protective layer 40 is partially located within the first area A1 and partially within the second area A2, the first protective layer 40 includes first openings 44 in communication with the pixel openings 31, and the first electrodes 51 are exposed to the first openings 44. With such a design, in addition to separating the mark portion 21 from the pixel definition layer 30, the first protective layer 40 may also cover part of the structure of the first electrode 51. In this way, the first protective layer 40 may be of an entire-surface structure, and during preparation of the first protective layer 40, the first protective layer 40 can be prepared without the need for a fine metal mask, thereby reducing preparation costs.

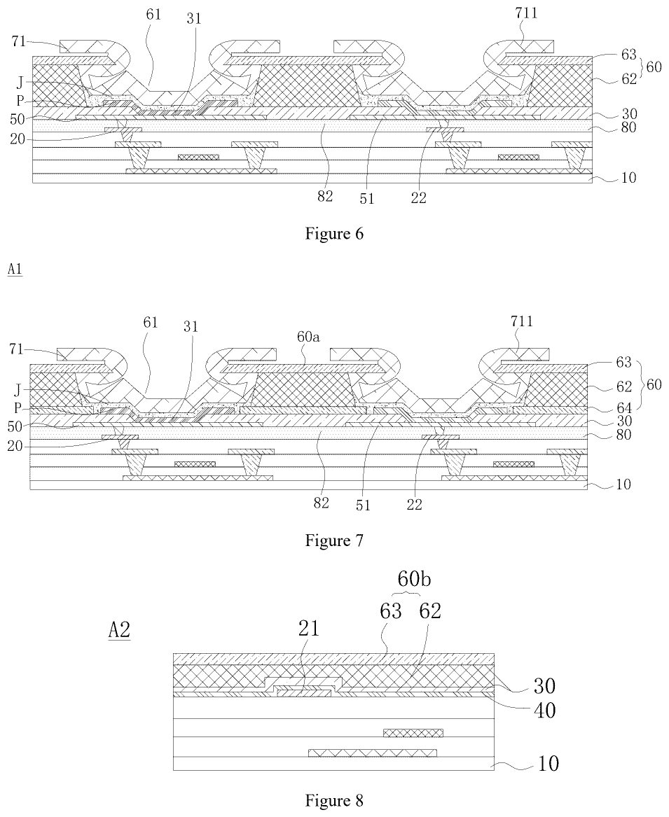

In some embodiments, referring to FIG. 6, the display panel further includes an isolation structure 60 arranged on a side of the pixel definition layer 30 facing away from the substrate 10. The isolation structure 60 encloses isolation openings 61 in communication with the pixel openings 31.

The isolation structure 60 is a partition structure in the display panel that is used to form spaced-apart parts of part of film layer structures without the need for a fine metal mask. In one embodiment, the display panel further includes a light-emitting functional layer located on the side of the first electrode layer 50 facing away from the substrate 10. The light-emitting functional layer includes light-emitting structures P located in the pixel openings 31. Further, in one embodiment, the display panel further includes a second electrode layer located on the side of the light-emitting functional layer facing away from the substrate 10. The second electrode layer includes second electrodes J located in the isolation openings 61. The first electrodes 51 and the second electrodes J are used to drivingly control whether the light-emitting structures P emit light. As an example, the first electrodes 51 serve as anodes, and the second electrodes J serve as cathodes.

Relevant embodiment for the isolation structure 60 (also referred to as a partition structure or an isolation pillar) are described in patents CN 118251982 A, 202410864269.8, PCT/CN2024/098407, PCT/CN2024/102783, PCT/CN2024/098217, PCT/CN2024/099419 and PCT/CN2024/099072, the contents of which are incorporated herein by reference and will not repeated in the embodiments of the present application.

The isolation structure 60 may enclose isolation openings 61, a light-emitting structure P is at least partially located in an isolation opening 61, and the expression “the light-emitting structure P is at least partially located in the isolation opening 61” mentioned here means that an orthographic projection of the light-emitting structure P on the substrate 10 is at least partially located within an orthographic projection of the isolation opening 61 on the substrate 10, that is, a position of the light-emitting structure P corresponds to a position of the isolation opening 61. The same logic applies to the second electrodes J, and will not be described in detail in the embodiments of the present application.

The light-emitting structures P include, but are not limited to, at least two of red light-emitting structures P for emitting red light, green light-emitting structures P for emitting green light, and blue light-emitting structures P for emitting blue light. A single light-emitting structure P may include stacked film layer structures, and a corresponding film layer composition of the light-emitting structure P is not limited in the embodiments of the present application. In one embodiment, the light-emitting structure P may include stacked film layers such as a hole inject layer (HIL), a hole transport layer (HTL), a light-emitting layer, an electron transport layer (ETL), and an electron inject layer (EIL). In some other embodiments, the single light-emitting structure P may include stacked light-emitting layers, and a charge generation layer is provided between adjacent light-emitting layers.

Next, a preparation process of the light-emitting functional layer and the second electrode layer will be described in detail in the embodiments of the present application. As an example in which the preparation of the green light-emitting structures P follows the preparation of the red light-emitting structures P, due to the omission of a fine metal mask, a red light-emitting material corresponding to the red light-emitting structures P and an electrode material corresponding to the red light-emitting structures P first fall into the isolation openings 61, the red light-emitting material and the electrode material in part of the isolation openings 61 are then selectively etched away, and the red light-emitting material and the electrode material in part of the isolation openings 61 are retained to form the red light-emitting structures P and the first electrodes 51 corresponding thereto. After that, a green light-emitting material and an electrode material corresponding to the green light-emitting structures P fall into the isolation openings 61, the green light-emitting material and the electrode material in part of the isolation openings 61 are then selectively etched away, and the green light-emitting material and the electrode material in part of the isolation openings 61 are retained to form the green light-emitting structures P and the first electrodes 51 corresponding thereto.

During preparation of the light-emitting structures P of color types, since the preparation of the light-emitting structures P of each color is often accompanied by an etching process, the mark portion 21 is easily affected by multiple etching processes during manufacturing of the light-emitting structures P, resulting in the risk of the mark portion 21 being damaged by etching. In view of this, in the embodiments of the present application, a dual protection effect on the mark portion 21 is provided by means of the first protective layer 40 and the pixel definition layer 30, reducing the risk of the mark portion 21 being damaged by etching, improving the alignment precision in subsequent manufacturing processes, and improving the reliability of the display panel.

A relative relationship between the isolation structure 60 and the second electrodes J is not limited in the embodiments of the present application. In one embodiment, the isolation structure 60 includes a conductive structure. The second electrodes J are electrically connected to the conductive structure. With such a design, the conductive structure in the isolation structure 60 can be used to transmit power signals corresponding to the second electrodes J. The second electrodes J can be arranged in contact with the conductive structure to receive and transmit the power signal, to meet the lighting requirements corresponding to the light-emitting structures P.

In some embodiments, as shown in FIG. 6, the isolation structure 60 includes a first isolation portion 62 and a second isolation portion 63 located on a side of the first isolation portion 62 facing away from the substrate 10. An orthographic projection of the first isolation portion 62 on the substrate 10 is located within an orthographic projection of the second isolation portion 63 on the substrate 10.

as can be seen from the foregoing, the provision of the isolation structure 60 enables the light-emitting functional layer to form spaced-apart light-emitting structures without the need for a fine metal mask, thereby reducing the preparation costs of the display panel. The isolation structure 60 includes the first isolation portion 62 and the second isolation portion 63 arranged sequentially in a direction away from the substrate 10, the orthographic projection of the first isolation portion 62 on the substrate 10 is located within the orthographic projection of the second isolation portion 63 on the substrate 10, and further, the orthographic projection of the second isolation portion 63 covers and extends beyond the orthographic projection of the first isolation portion 62.

The specific size and shape of the first isolation portion 62 and the second isolation portion 63 are not limited in the embodiments of the present application. As an example, the isolation structure 60 may have a T-shaped longitudinal cross section. This design helps to prevent the light-emitting material from extending to a side wall of the second isolation portion 63 along a side wall of the first isolation portion 62 during preparation of the light-emitting functional layer, and the light-emitting structures P corresponding to different isolation openings 61 can be prepared and separated from one another without the need for a fine metal mask. The same logic applies to the preparation of the second electrodes J, and will not be described in detail in the embodiments of the present application.

In some embodiments, the first isolation portion 62 includes a conductive material, and the second isolation portion 63 is electrically connected to the second electrodes J. In other words, the conductive structure includes the first conductor portions 22, and the first conductor portions 22 may be used to transmit power signals to the second electrodes J.

It should be noted that the second electrodes J may be in direct contact with the first isolation portion 62 to achieve electrical connection between the first isolation portion 62 and the second electrodes J. Alternatively, the conductive structure may further include another structure besides the first isolation portion 62, which is in contact with both the first isolation portion 62 and the second electrodes J to achieve electrical connection between the first isolation portion 62 and the second electrodes J.

In the embodiments of the present application, the first isolation portion 62 not only forms a T-shaped structure together with the second isolation portion 63 to meet the requirements of isolating different light-emitting structures P from the second electrodes J, but also includes a conductive material to meet the requirements of transmitting the power signals corresponding to the second electrodes J and satisfying the display needs of the display panel, providing better practicability.

In some embodiments, as shown in FIG. 7, the isolation structure 60 further includes a third isolation portion 64 located on a side of the first isolation portion 62 facing the substrate 10. The orthographic projection of the first isolation portion 62 on the substrate 10 is located within an orthographic projection of the third isolation portion 64 on the substrate 10. Further, the orthographic projection of the third isolation portion 64 on the substrate 10 covers and extends beyond the orthographic projection of the first isolation portion 62 on the substrate 10.

In the embodiments of the present application, by adding the third isolation portion 64, the second electrodes J can be in contact with a surface of the third isolation portion 64 facing away from the substrate 10, thereby increasing a contact area between the isolation structure 60 and the second electrodes J. Further, in one embodiment, the third isolation portion 64 includes a conductive material, and the third isolation portion 64 is arranged in contact with the second electrodes J. In this way, both the first isolation portion 62 and the third isolation portion 64 can be used to transmit power signals, and the transmission reliability of the power signals between the isolation structure 60 and the second electrodes J can be improved, and the use reliability of the display panel can be improved.

In some embodiments, referring to FIGS. 7 and 8, the isolation structure 60 includes a first isolation structure 60a located within the first area A1 and a second isolation structure 60b located within the second area A2. The orthographic projection of the mark portion 21 on the substrate 10 is located within an orthographic projection of the second isolation structure 60b on the substrate 10.

The first isolation structure 60a is a partial structure of the isolation structure 60 within the first area A1, and the isolation openings 61 are enclosed by the first isolation structure 60a. The second isolation structure 60b is a partial structure of the isolation structure 60 within the second area A2, where the second isolation structure 60b may enclose an open structure, or the second isolation structure 60b may not enclose an open structure, which is not limited in the embodiments of the present application.

Specific film layer compositions of the first isolation structure 60a and the second isolation structure 60b are not limited in the embodiments of the present application. In one embodiment, each of the first isolation structure 60a and the second isolation structure 60b includes the first isolation portion 62 and the second isolation portion 63 that are stacked.

Further, in the embodiments of the present application, the orthographic projection of the second isolation structure 60b on the substrate 10 overlaps with the orthographic projection of the mark portion 21 on the substrate 10, that is, in addition to the first protective layer 40 and the pixel definition layer 30, the second isolation structure 60b can also cover and protect the mark portion 21, which can further reduce the adverse effects of multiple etching processes during manufacturing of the light-emitting structures P on the mark portion 21, improve the structural reliability of the mark portion 21 and help to improve the alignment precision in subsequent manufacturing processes.

Certainly, in other embodiments, the orthographic projection of the second isolation structure 60b on the substrate 10 may also be located outside the orthographic projection of the mark portion 21 on the substrate 10. In this way, the shielding of the mark portion 21 by the isolation structure 60 can be decreased, facilitating the identification of the mark portion 21 by using optical principles during alignment.

In some embodiments, as shown in FIGS. 6 and 7, the display panel further includes the light-emitting functional layer arranged on the side of the first electrode layer 50 facing away from the substrate 10 and a first encapsulation layer 71 arranged on the side of the light-emitting functional layer facing away from the substrate 10. The first encapsulation layer 71 includes encapsulation portions 711 located within the isolation openings 61.

The first encapsulation layer 71 mainly serves an encapsulation and protection function, and the first encapsulation layer 71 includes the encapsulation portions 711 arranged corresponding to the isolation openings 61. That is, the preparation of the first encapsulation layer 71 is affected by the isolation structure, and accordingly spaced-apart encapsulation portions 711 corresponding to the different light-emitting structures P are formed, to separately encapsulate the different light-emitting structures P and improve the encapsulation reliability. The specific shape and size of the encapsulation portions 711 are not limited in the embodiments of the present application. In one embodiment, due to factors such as a material composition and film formation method in the first encapsulation layer 71, a partial structure of an encapsulation portion 711 may extend relative to a side wall of the isolation structure 60 and extend to a side of the isolation structure 60 facing away from the substrate 10.

In the embodiments of the present application, the first encapsulation layer 71 includes encapsulation portions 711 corresponding to the different light-emitting structures P and spaced apart from one another, and the different encapsulation portions 711 may encapsulate and protect the different light-emitting structures P, thereby improving an encapsulation and protection effect on the light-emitting structures P and reducing the risk of moisture or the like intruding into the light-emitting structures P. In one embodiment, the first encapsulation layer 71 includes an inorganic material.

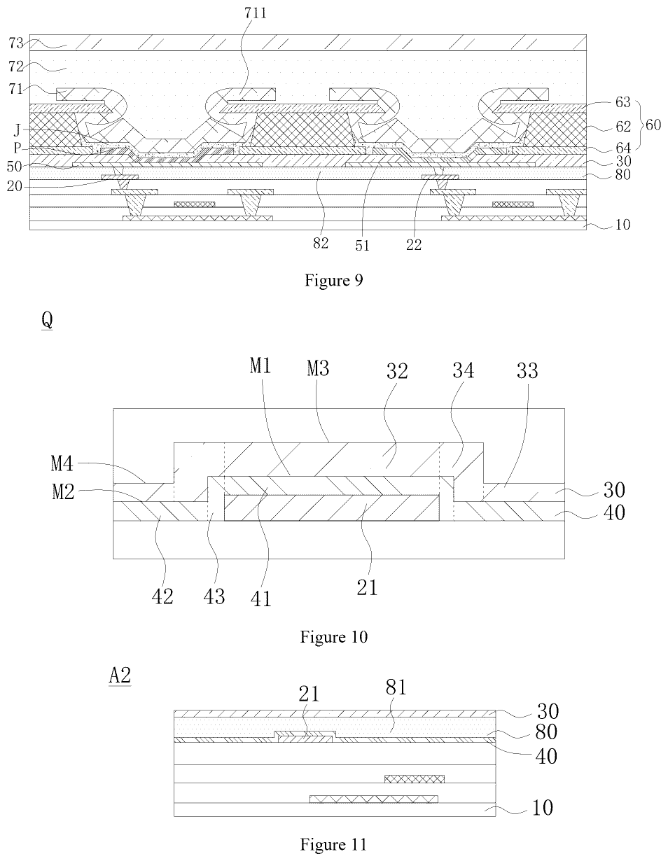

In some embodiments, referring to FIG. 9, the display panel further includes a second encapsulation layer 72 located on a side of the first encapsulation layer 71 facing away from the substrate 10. The second encapsulation layer 72 covers encapsulation portions 711.

Different from the first encapsulation layer 71, the second encapsulation layer 72 may be of an entire-surface structure and cover encapsulation portions 711. The material compositions of the first encapsulation layer 71 and the second encapsulation layer 72 are not limited in the embodiments of the present application. In one embodiment, the first encapsulation layer 71 includes the inorganic material, and the second encapsulation layer 72 includes an organic material.

In some embodiments, the display panel further includes a third encapsulation layer 73 located on a side of the second encapsulation layer 72 facing away from the substrate 10. The second encapsulation layer 72 and the third encapsulation layer 73 are each of an entire-surface structure. Further, the first encapsulation layer 71, the second encapsulation layer 72 and the third encapsulation layer 73 may jointly form a thin-film encapsulation structure, to further improve the corresponding encapsulation reliability of the display panel. In one embodiment, the third encapsulation layer 73 includes an inorganic material.

In some embodiments, referring to FIG. 10, the first protective layer 40 includes a first sub-portion 41 located on a side of the mark portion 21 facing away from the substrate 10, and a second sub-portion 42 located on a peripheral side of the mark portion 21. The first sub-portion 41 has a first surface M1 facing away from the substrate 10, the second sub-portion 42 has a second surface M2 facing away from the substrate 10, and a plane of the first surface M1 is located on a side of a plane of the second surface M2 that faces away from the substrate 10.

The first sub-portion 41 is a partial structure of the first protective layer 40 covering the mark portion 21, and the second sub-portion 42 is a partial structure of a first protective portion that is located on the peripheral side of the mark portion 21. The first sub-portion 41 and the second sub-portion 42 may be integrally connected by means of other structures, or the first sub-portion 41 and the second sub-portion 42 may be disconnected, which is not limited in the embodiments of the present application.

The first surface M1 is a surface of the first sub-portion 41 facing away from the substrate 10, and the second surface M2 is a surface of the second sub-portion 42 facing away from the substrate 10. Since the mark portion 21 has a certain thickness dimension, the plane of the first surface M1 is located on the side of the plane of the second surface M2 that faces away from the substrate 10, and a certain step difference exists between the plane of the first surface M1 and the plane of the second surface M2. Further, during positioning procedure, the position of the mark portion 21 can be identified by means of the step difference between the first surface M1 and the second surface M2, thereby realizing the identification of the mark portion 21, meeting the requirements of positioning and identification, and providing better practicability.

In some embodiments, as shown in FIG. 10, the first protective layer 40 and the pixel definition layer 30 are arranged in close contact with each other within the second area A2.

In the embodiments of the present application, since the first protective layer 40 and the pixel definition layer 30 are arranged in close contact with each other within the second area A2, the step difference generated at the first surface M1 and the second surface M2 results in a step difference generated at a corresponding position on the pixel definition layer 30. In one embodiment, the pixel definition layer 30 includes a third sub-portion 32 on a side of the first sub-portion 41 facing away from the substrate 10, and a fourth sub-portion 33 located on a peripheral side of the first sub-portion 41. The third sub-portion 32 has a third surface M3 facing away from the substrate 10, the fourth sub-portion 33 has a fourth surface M4 facing away from the substrate 10, and a plane of the third surface M3 is located on a side of a plane of the fourth surface M4 that faces away from the substrate 10.

With such a design, during positioning procedure, the position of the mark portion 21 can be identified by means of a step difference between the plane of the third surface M3 and the plane of the fourth surface M4, thereby realizing the identification of the mark portion 21, meeting the requirements of positioning and identification, and providing better practicability.

In some embodiments, the first protective layer 40 further includes a fifth sub-portion 43 connecting the first sub-portion 41 and the second sub-portion 42, and the fifth sub-portion 43 is arranged in close contact with a side wall of the mark portion 21.

In the embodiments of the present application, the fifth sub-portion 43 not only integrally connects the first sub-portion 41 and the second sub-portion 42, but also is arranged in close contact with the side wall of the mark portion 21 to protect the side wall of the mark portion 21, reducing the adverse effects of the etching processes on the side wall of the mark portion 21, that is, reducing the lateral etching impact on the mark portion 21, and further improving the structural reliability of the mark portion 21.

In some embodiments, the first conductor layer 20 includes a first titanium metal layer, an aluminum metal layer and a second titanium metal layer that are stacked, that is, the mark portion 21 may be formed by a three-layer stack of titanium-aluminum-titanium. In general, the aluminum metal layer is more susceptible to damage caused by lateral etching. In view of this, in the embodiments of the present application, the fifth sub-portion 43 is arranged in close contact with the side wall of the mark portion 21, and by means of the fifth sub-portion 43, the lateral etching impact on the aluminum metal layer is reduced, thereby improving the reliability.

In some embodiments, the pixel definition layer 30 includes the third sub-portion 32 located on the side of the first sub-portion 41 facing away from the substrate 10, the fourth sub-portion 33 located on the peripheral side of the first sub-portion 41, and a sixth sub-portion 34 connecting the third sub-portion 32 and the fourth sub-portion 33.

In the embodiments of the present application, both the fifth sub-portion 43 and the sixth sub-portion 34 can cover and protect the side wall of the mark portion 21, thereby achieving a dual protection effect on the side wall of the mark portion 21, further reducing the lateral etching impact on the mark portion 21, improving the structural reliability of the mark portion 21, and thus improving the positioning precision in subsequent manufacturing processes.

In some embodiments, as shown in FIGS. 2 and 3, the display panel further includes a planarization layer 80 arranged between the pixel definition layer 30 and the first conductor layer 20. An orthographic projection of the planarization layer 80 on the substrate 10 is located outside the orthographic projection of the mark portion 21 on the substrate 10.

The planarization layer 80 is a film layer in the display panel that is used to provide a flat surface. A surface of the planarization layer 80 facing away from substrate 10 is generally parallel to a plane of the substrate 10, and the planarization layer 80 helps to reduce the difficulty in preparing other film layers after the planarization layer 80 and improve the preparation precision thereof.

The planarization layer 80 is arranged in the pixel definition layer 30 and the first conductor layer 20 and is at least partially located within the first area A1, and the planarization layer 80 may provide a flat surface for the preparation of the first electrodes 51, thereby improving the preparation precision of the first electrodes 51 and reducing the preparation difficulty thereof.

Further, in the embodiments of the present application, the orthographic projection of the planarization layer 80 on the substrate 10 is located outside the orthographic projection of the mark portion 21 on the substrate 10, that is, the planarization layer 80 and the mark portion 21 are arranged in a staggered manner, and the impact of the planarization layer 80 on the corresponding step difference at the position of the mark portion 21 can be reduced. In this way, the position of the mark portion 21 can be identified by means of the step difference during positioning procedure, meeting the requirements of positioning the display panel.

It should be noted that the planarization layer 80 may not be arranged within the second area A2 at all, or the planarization layer 80 may be partially arranged within second area A2, as long as a partial structure of the planarization layer 80 located within the second area A2 is arranged in a staggered manner with the mark portion 21. In one embodiment, the planarization layer 80 is located within the first area A1 and outside the second area A2.

In some embodiments, the first conductor layer 20 includes first conductor portions 22 located within the first area A1, and the planarization layer 80 covers the first conductor portions 22.

In the embodiments of the present application, the first conductor portion 22 is a conductor structure in the first conductor layer 20 that is located within the first area A1 and is used for transmitting a specific signal, and the planarization layer 80 may be a film layer structure insulating and separating the first conductor portion 22 from the first electrode 51. On this basis, the planarization layer 80 may also provide a flat surface for the preparation of the first electrode 51, thereby improving the reliability of the first electrode 51.

In some embodiments, referring to FIGS. 2 and 11, the display panel further includes a planarization layer 80 arranged between the pixel definition layer 30 and the first conductor layer 20. The orthographic projection of the mark portion 21 on the substrate 10 is located within the orthographic projection of the planarization layer 80 on the substrate 10, and the planarization layer 80 is located between the first protective layer 40 and the pixel definition layer 30.

In the embodiments of the present application, the orthographic projection of the planarization layer 80 on the substrate 10 overlaps with the orthographic projection of the mark portion 21 on the substrate 10, and the mark portion 21 can be protected by a three-layer structure of the first protective layer 40, the planarization layer 80 and the pixel definition layer 30, thereby further improving the protection effect on the mark portion 21, and reducing the risk of damage to the mark portion 21.

In addition, the planarization layer 80 may be completely located within the second area A2, or the planarization layer 80 may be partially located within the first area A1 and partially within the second area A2, which is not limited in the embodiments of the present application. In one embodiment, the planarization layer 80 is partially located within the first area A1 and partially within the second area A2, and the partial structure of the planarization layer 80 located within the first area A1 can also provide a flat surface for the preparation of the first electrodes 51, thereby improving the preparation precision of the first electrodes 51.

In some embodiments, the planarization layer 80 includes a first flat portion 81 located within the second area A2 and a second flat portion 82 located within the first area A1. The first flat portion 81 and the second flat portion 82 are integrally connected. This design allows the planarization layer 80 to form an entire-surface structure, thereby reducing the difficulty in preparing the planarization layer 80.

In some embodiments, the planarization layer 80 includes a first flat portion 81 located within the second area A2 and a second flat portion 82 located within the first area A1. A surface of the first flat portion 81 facing away from the substrate 10 is parallel to a plane of the substrate 10.

In the embodiments of the present application, the first flat portion 81 can provide a flat surface for a partial structure of the pixel definition layer 30 within the second area A2, thereby improving the preparation precision of the display panel at the second area A2. Further, in one embodiment, the planarization layer 80 includes a second flat portion 82 located within the first area A1, and the surface of the first flat portion 81 facing away from the substrate 10 and a surface of the second flat portion 82 facing away from the substrate 10 are located in the same plane. In this way, there is no need to differentiate the first flat portion 81, reducing the difficulty in preparing the planarization layer 80.

It should be noted that since the surface of the first flat portion 81 facing away from the substrate 10 is parallel to the plane of the substrate 10, there may be no step difference in a region of the display panel corresponding to the mark portion 21, and therefore, it is necessary to identify and position the mark portion 21 by means of optical principles. On this basis, the orthographic projection of the mark portion 21 on the substrate 10 needs to be at least partially located outside the orthographic projection of the first electrode layer 50 on the substrate 10, to meet the requirements of positioning and identification.

In some embodiments, the first protective layer 40 includes an inorganic material and is arranged in contact with the mark portion 21.

Compared with other types of materials, by configuring the first protective layer 40 to include the inorganic material, it is possible to reduce the intrusion of moisture or the like through the first protective layer 40 into the mark portion 21, thereby reducing damage to the mark portion 21 caused by moisture or the like, and improving the structural reliability of the mark portion 21.

In some embodiments, the pixel definition layer 30 includes an inorganic material, and two inorganic layers provide dual protection for the mark portion 21, which can further reduce damage to the mark portion 21 caused by moisture or the like while reducing the etching damage to the mark portion 21 caused by the etching processes, thereby improving the structural reliability of the mark portion 21.

Further, in one embodiment, the orthographic projection of the mark portion 21 on the substrate 10 is located within the orthographic projection of the planarization layer 80 on the substrate 10, and the planarization layer 80 includes an organic material.

In the embodiments of the present application, the first protective layer 40, the planarization layer 80 and the pixel definition layer 30 form an inorganic-organic-inorganic structure for protecting the mark portion 21, and a thin-film encapsulation structure covering the mark portion 21 can also be formed while enhancing the protection effect on the mark portion 21. The risk of moisture or the like intruding into the mark portion 21 can be further reduced by means of the thin film structure, thereby improving the structural reliability of the mark portion 21.

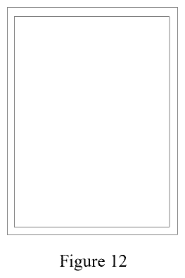

In one embodiment, referring to FIG. 12, the embodiments of the present application provide a display device, including a display panel in any one of the proceeding implementations.

What is claimed is:

1. A display panel having a first area and a second area located on at least one side of the first area, the display panel comprising:
a substrate;
a first conductor layer arranged on a side of the substrate, the first conductor layer comprising a mark portion located within the second area;
a pixel definition layer arranged on a side of the first conductor layer facing away from the substrate; and
a first protective layer arranged between the pixel definition layer and the first conductor layer, an orthographic projection of the mark portion on the substrate being located within orthographic projections of the first protective layer and the pixel definition layer on the substrate.

2. The display panel according to claim 1, wherein the display panel further comprises a first electrode layer arranged between the pixel definition layer and the first conductor layer, the first electrode layer comprising first electrodes located within the first area, the pixel definition layer enclosing pixel openings, and the first electrodes being exposed to the pixel openings;
the first conductor layer comprises first conductor portions located within the first area, an orthographic projection of a first conductor portion on the substrate being located within an orthographic projection of a first electrode on the substrate; and
the first conductor portion is electrically connected to the first electrode.

3. The display panel according to claim 2, wherein the first electrode layer further comprises a second conductor portion located within the second area, an orthographic projection of the second conductor portion on the substrate being located within the orthographic projection of the mark portion on the substrate;
the first electrode is insulated from the second conductor portion; and
the second conductor portion is located between the first protective layer and the pixel definition layer.

4. The display panel according to claim 1, wherein the first conductor layer comprises first electrodes located within the first area, the pixel definition layer encloses pixel openings, and the first electrodes are exposed to the pixel openings;
the mark portion is insulated from the first electrodes; and
the first electrodes are arranged in close contact with the pixel definition layer, and the mark portion is arranged at a distance from the pixel definition layer.

5. The display panel according to claim 4, wherein the first protective layer is located within the second area and outside the first area;
or the first protective layer is partially located within the first area and partially within the second area, the first protective layer comprises first openings in communication with the pixel openings, and the first electrodes are exposed to the first openings.

6. The display panel according to claim 2, wherein the display panel further comprises an isolation structure arranged on a side of the pixel definition layer facing away from the substrate, the isolation structure enclosing isolation openings in communication with the pixel openings;
the display panel further comprises a light-emitting functional layer located on a side of the first electrode layer facing away from the substrate, the light-emitting functional layer comprising light-emitting structures arranged in the pixel openings;
the display panel further comprises a second electrode layer located on a side of the light-emitting functional layer facing away from the substrate, the second electrode layer comprising second electrodes arranged in the isolation openings; and
the isolation structure comprises a conductive structure, the second electrodes being electrically connected to the conductive structure.

7. The display panel according to claim 6, wherein the isolation structure comprises a first isolation portion and a second isolation portion located on a side of the first isolation portion facing away from the substrate, an orthographic projection of the first isolation portion on the substrate being located within an orthographic projection of the second isolation portion on the substrate; and
the isolation structure further comprises a third isolation portion located on a side of the first isolation portion facing the substrate, the orthographic projection of the first isolation portion on the substrate being located within an orthographic projection of the third isolation portion on the substrate.

8. The display panel according to claim 7, wherein the display panel further comprises the second electrode layer located on the side of the first electrode layer facing away from the substrate, the second electrode layer comprising second electrodes arranged in the isolation openings;
the first isolation portion comprises a conductive material, the second electrodes being electrically connected to the first isolation portion;
the isolation structure further comprises the third isolation portion located on the side of the first isolation portion facing the substrate, the orthographic projection of the first isolation portion on the substrate being located within the orthographic projection of the third isolation portion on the substrate; and
the third isolation portion comprises a conductive material and is arranged in contact with the second electrodes.

9. The display panel according to claim 6, wherein the isolation structure comprises a first isolation structure located within the first area and a second isolation structure located within the second area, the orthographic projection of the mark portion on the substrate being located within an orthographic projection of the second isolation structure on the substrate;
the mark portion is insulated from the first conductor portion; and
the mark portion is insulated from the second isolation structure.

10. The display panel according to claim 6, further comprises the light-emitting functional layer arranged on the side of the first electrode layer facing away from the substrate and a first encapsulation layer arranged located on a side of the light-emitting functional layer facing away from the substrate, the first encapsulation layer comprising encapsulation portions located in the isolation openings,
wherein the first encapsulation layer comprises an inorganic material.

11. The display panel according to claim 10, wherein the display panel further comprises a second encapsulation layer located on a side of the first encapsulation layer facing away from the substrate, the second encapsulation layer covering a plurality of encapsulation portions;
the first encapsulation layer comprises the inorganic material, and the second encapsulation layer comprises an organic material;
the display panel further comprises a third encapsulation layer located on a side of the second encapsulation layer facing away from the substrate; and
the third encapsulation layer comprises an inorganic material.

12. The display panel according to claim 1, wherein the first protective layer comprises a first sub-portion located on a side of the mark portion facing away from the substrate, and a second sub-portion located on a peripheral side of the mark portion; and
the first sub-portion has a first surface facing away from the substrate, the second sub-portion has a second surface facing away from the substrate, and a plane of the first surface is located on a side of a plane of the second surface that faces away from the substrate.

13. The display panel according to claim 12, wherein the first protective layer and the pixel definition layer are arranged in close contact with each other within the second area;
the pixel definition layer comprises a third sub-portion located on a side of the first sub-portion facing away from the substrate, and a fourth sub-portion located on a peripheral side of the first sub-portion; and
the third sub-portion has a third surface facing away from the substrate, the fourth sub-portion has a fourth surface facing away from the substrate, and a plane of the third surface is located on a side of a plane of the fourth surface faces away from the substrate.

14. The display panel according to claim 12, wherein the first protective layer further comprises a fifth sub-portion connecting the first sub-portion and the second sub-portion;
the fifth sub-portion is arranged in close contact with a side wall of the mark portion;
the first conductor layer comprises a first titanium metal layer, an aluminum metal layer and a second titanium metal layer stacked sequentially; and
the pixel definition layer comprises a third sub-portion located on a side of the first sub-portion facing away from the substrate, a fourth sub-portion located on a peripheral side of the first sub-portion, and a sixth sub-portion connecting the third sub-portion and the fourth sub-portion.

15. The display panel according to claim 1, wherein the display panel further comprises a planarization layer arranged between the pixel definition layer and the first conductor layer, an orthographic projection of the planarization layer on the substrate being located outside the orthographic projection of the mark portion on the substrate;
the planarization layer is located within the first area and outside the second area; and
the first conductor layer comprises first conductor portions located within the first area, and the planarization layer covers the first conductor portions.

16. The display panel according to claim 1, wherein the display panel further comprises a planarization layer arranged between the pixel definition layer and the first conductor layer, the orthographic projection of the mark portion on the substrate being located within an orthographic projection of the planarization layer on the substrate, and the planarization layer being located between the first protective layer and the pixel definition layer.

17. The display panel according to claim 16, wherein the planarization layer is partially located within the first area and partially within the second area; and
the planarization layer comprises a first flat portion located within the second area and a second flat portion located within the first area, the first flat portion and the second flat portion being integrally connected.

18. The display panel according to claim 16, wherein the planarization layer comprises a first flat portion located within the second area, a surface of the first flat portion facing away from the substrate being parallel to a plane of the substrate; and
the planarization layer comprises a second flat portion located within the first area, a surface of the second flat portion facing away from the substrate and the surface of the first flat portion facing away from the substrate being located in the same plane.

19. The display panel according to claim 1, wherein the first protective layer comprises an inorganic material and is arranged in contact with the mark portion;
the pixel definition layer comprises an inorganic material;
the display panel further comprises a planarization layer arranged between the pixel definition layer and the first conductor layer, the orthographic projection of the mark portion on the substrate being located within an orthographic projection of the planarization layer on the substrate; and
the planarization layer comprises an organic material.

20. A display device, comprising a display panel having a first area and a second area located on at least one side of the first area, the display panel comprising:
a substrate;
a first conductor layer arranged on a side of the substrate, the first conductor layer comprising a mark portion located within the second area;
a pixel definition layer arranged on a side of the first conductor layer facing away from the substrate; and
a first protective layer arranged between the pixel definition layer and the first conductor layer, an orthographic projection of the mark portion on the substrate being located within orthographic projections of the first protective layer and the pixel definition layer on the substrate.
